(19) United States
(12) Patent Application Publication
(10) Pub. No.: US 2013/0213910 A1
(43) Pub. Date: Aug. 22, 2013

(54) BOAT FOR LOADING SEMICONDUCTOR SUBSTRATES

(71) Applicant: SAMSUNG ELECTRONICS CO., LTD., (US)

(72) Inventors: Sung-Ho KANG, Osan-si (KR); Bong-Jin KUH, Suwon-si (KR); Ki-Seok KIM, Osan-si (KR); Ki-Chul KIM, Seongnam-si (KR); Ik-Soo KIM, Yongin-si (KR); Yong-Kyu JOO, Hwaseong-si (KR); Sang-Cheol HA, Suwon-si (KR)

(73) Assignee: SAMSUNG ELECTRONICS CO., LTD., Suwon-Si (KR)

(21) Appl. No.: 13/671,989

(22) Filed: Nov. 8, 2012

(30) Foreign Application Priority Data
Feb. 20, 2012 (KR) 10-2012-0016976

(51) Int. Cl. H01L 21/683

(52) U.S. Cl. CPC H01L 21/683
USPC 211/41.18

(57) ABSTRACT

Provided is a boat for loading semiconductor substrates that includes a top plate and a bottom plate separated from each other, a rod extending from the bottom plate to the top plate and disposed between the top plate and the bottom plate, a plurality of buffer plates disposed between the top plate and the bottom plate and separated from each other by a first distance along a lengthwise direction of the rod, and a support provided between a first buffer plate and a second buffer plate which neighbor each other and supporting a loaded semiconductor substrate.

This application claims priority under 35 U.S.C. §119 to Korean Patent Application No. 10-2012-0016976 filed on Feb. 20, 2012 in the Korean Intellectual Property Office, the disclosure of which is incorporated herein by reference in its entirety.

### BACKGROUND

1. Field of the Inventive concept

The present inventive concepts relate to a boat for loading semiconductor substrates.

2. Description of the Related Art

Batch-type fabrication equipment is one type of semiconductor device fabrication equipment. To process multiple wafers in a single process using the batch-type fabrication equipment, a boat loaded with wafers may be used. Specifically, a boat loaded with wafers may be loaded into the batch-type fabrication equipment, and then a process may be performed. In the boat, a predetermined number of wafers may be loaded in a vertical direction with equal spaces between them.

However, if a smaller number of wafers than the predetermined number of wafers are loaded into the boat, the wafers cannot be equally spaced apart from each other. Accordingly, some wafers may be affected relatively more or relatively less by a processing gas, thus reducing processing yields. To prevent a reduction in processing yield, when the number of wafers available is smaller than the predetermined number, a number of dummy wafers corresponding to the difference from the predetermined number may be loaded to make the wafers equally spaced apart from each other.

However, the dummy wafers are not made into products but are discarded in the end. Therefore, the use of the dummy wafers may increase manufacturing costs of semiconductor devices. Moreover, the entire processing time may be increased by the time required to additionally load the dummy wafers into the boat.

### SUMMARY

Some example embodiments of the present inventive concepts provide a boat for loading semiconductor substrates, the boat preventing or minimizing a reduction in processing yield without using dummy wafers by using buffer plates.

However, the present inventive concepts are not restricted to example embodiments set forth herein. The above and other aspects of the present inventive concepts will become more apparent to one of ordinary skill in the art to which the present inventive concept pertains by referencing the detailed description of the present inventive concepts given below.

According to one example embodiment, a boat for loading semiconductor substrates may include a top plate and a bottom plate separated from each other, a rod extending from the bottom plate to the top plate and disposed between the top plate and the bottom plate, a plurality of buffer plates disposed between the top plate and the bottom plate and separated from each other by a first distance along a lengthwise direction of the rod, and a support provided between a first buffer plate and a second buffer plate which neighbor each other and configured to support a loaded semiconductor substrate.

A number of the buffer plates may be equal to or greater than three.

A support may be a plurality of supports, which are disposed between a respective neighboring pair of the buffer plates. A same number of the supports may be disposed between each neighboring pair of the buffer plates.

A distance between the first buffer plate and the support may be different from a distance between the second plate and the support.

Side surfaces of the buffer plates may be configured to contact the rod.

The rod may be made of a same material as the buffer plates.

The buffer plates may have no apertures.

The support may be a slot in the rod, which protrudes from a top surface of one of the first and second buffer plates. The support may be a pin protruding from the rod.

According to another example embodiment, a boat for loading semiconductor substrates may include a first buffer plate, a second buffer plate facing the first buffer plate and separated from the first buffer plate, m first supports disposed between the first buffer plate and the second buffer plate and configured to support loaded semiconductor substrates, a third buffer plate facing the second buffer plate and separated from the second buffer plate, and in second supports disposed between the second buffer plate and the third buffer plate and configured to suppport loaded semiconductor substrates, and where in is a natural number equal to or greater than one.

A distance between the first buffer plate and the second buffer plate may be equal to a distance between the second buffer plate and the third buffer plate.

The boat may further include a rod extending from the first buffer plate to the third buffer plate and the rod may be configured to contact side surfaces of the first through third buffer plates.

The rod may be made of a same material as the first through third buffer plates.

The first and second supports may be slots in the rod.

According to an example embodiment, a boat for loading substrates, the boat may include a plurality of compartments and at least one support associated with each of the compartments configured to receive a substrate.

The compartments may have a same size.

The position of the support for each of the compartment may be the same.

The compartments may be defined by spaced, parallel plates.

### BRIEF DESCRIPTION OF THE DRAWINGS

The present inventive concepts will become more apparent by describing in detail exemplary embodiments thereof with reference to the attached drawings, in which:

FIG. 1 is a perspective view of a boat according to an example embodiment;

FIG. 2 is a cross-sectional view of the boat shown in FIG. 1;

FIG. 3 is a cross-sectional view of the boat of FIG. 1 loaded with semiconductor substrates;

FIG. 4 is a plan view of a cross section of the boat, taken along the line IV-IV' of FIG. 3;

FIG. 5 is a cross-sectional view of semiconductor device fabrication equipment loaded with the boat of FIG. 3;

FIG. 6 is a cross-sectional view of a boat according to an example embodiment;

FIG. 7 is a cross-sectional view of a boat according to an example embodiment;

FIG. 8 is a perspective view of a boat according to an example embodiment;

FIG. 9 is a perspective view of a buffer plate included in the boat of FIG. 8;

FIG. 10 is a cross-sectional view of the boat shown in FIG. 8;

FIG. 11 is a cross-sectional view of the boat of FIG. 8 loaded with semiconductor substrates;

FIG. 12 is a plan view of a cross section of the boat, taken along the line XII-XII' of FIG. 11;

FIG. 13 is a cross-sectional view of a boat according to an example embodiment;

FIG. 14 is a cross-sectional view of a boat according to an example embodiment; and

FIG. 15 is a cross-sectional view of a boat according to an example embodiment.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF THE EMBODIMENTS

Example embodiments will now be described more fully with reference to the accompanying drawings. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. As used herein, the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning consistent with their meaning in the context of the relevant art, and will not be interpreted in an idealized or overly formal sense unless expressly so defined herein.

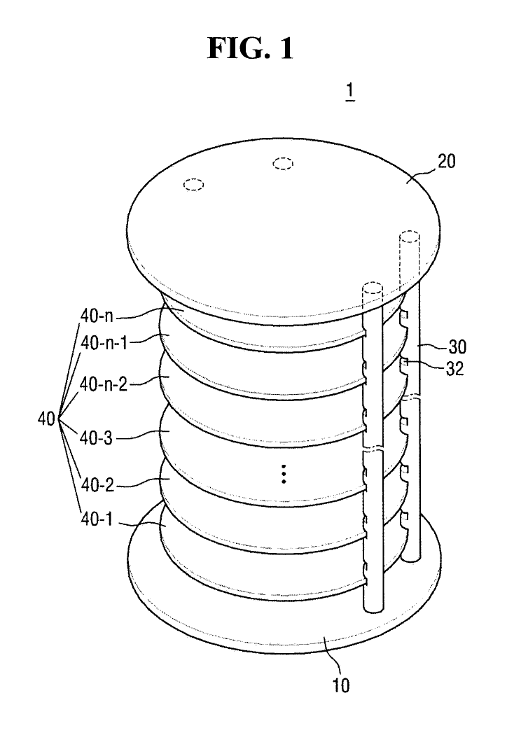

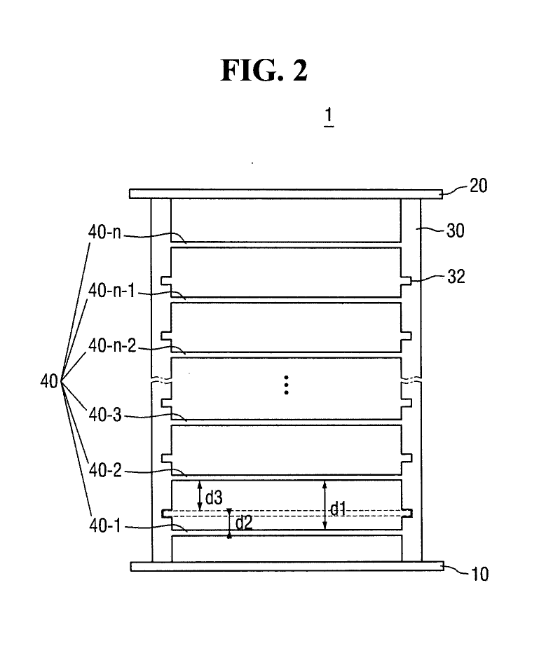

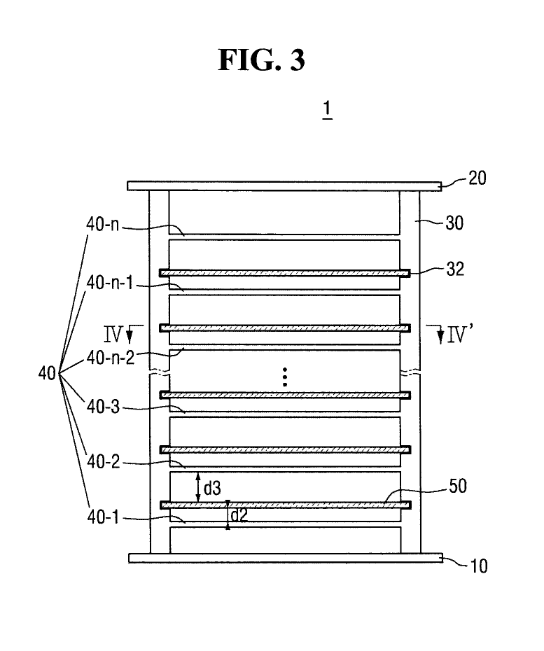

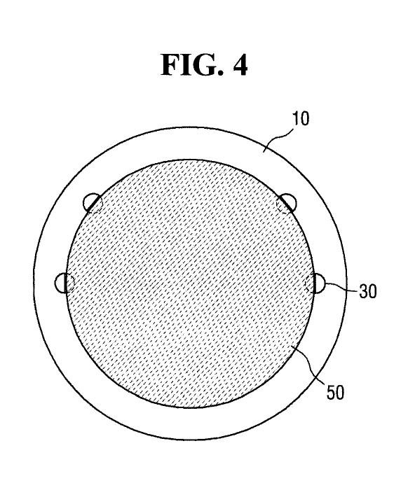

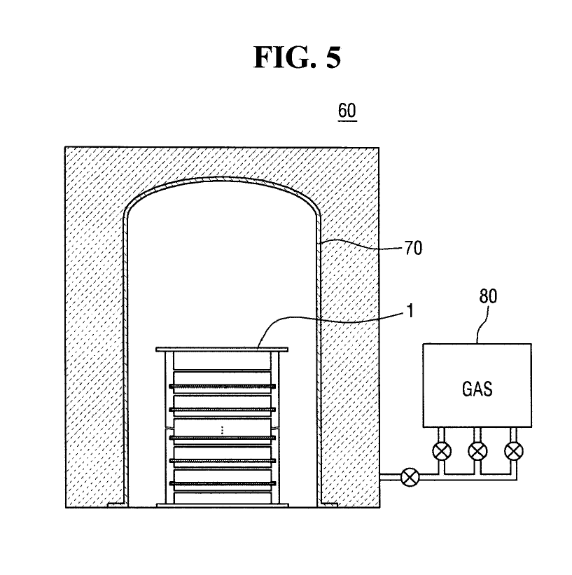

A boat for loading semiconductor substrates according to an example embodiment will be described with reference to FIGS. 1 through 5. FIG. 1 is a perspective view of a boat 1 according to an example embodiment. FIG. 2 is a cross-sectional view of the boat 1 shown in FIG. 1. FIG. 3 is a cross-sectional view of the boat 1 of FIG. 1 loaded with semiconductor substrates 50. FIG. 4 is a plan view of a cross section of the boat 1, taken along the line IV-IV' of FIG. 3. FIG. 5 is a cross-sectional view of semiconductor device fabrication equipment 60 loaded with the boat 1 of FIG. 3.

Referring to FIGS. 1 and 2, the boat 1 may include a bottom plate 10, a top plate 20, a plurality of rods 30, a plurality of buffer plates 40, and a plurality of supports.

The bottom plate 10 and the top plate 20 may be separated from each other. The bottom plate 10 and the top plate 20 may face each other. The rods 30, the buffer plates 40, and the semiconductor substrates 50 (see FIG. 3), which will be described later, may be placed in a space between the bottom plate 10 and the top plate 20.

The bottom plate 10 and the top plate 20 may be, but are not limited to, circular plates. In FIG. 1, no apertures are disposed in the bottom plate 10 and the top plate 20. However, example embodiments are not limited thereto, and apertures may be disposed in the bottom plate 10 and the top plate 20. The bottom plate 10 and the top plate 20 may contain at least one of, but are not limited to, quartz and silicon carbide (SiC).

The rods 30 may extend from the bottom plate 10 to the top plate 20 and may be arranged between the bottom plate 10 and the top plate 20. For example, the bottom plate 10 and the top plate 20 may be connected to each other by the rods 30.

In FIG. 4, four rods 30 are provided. However, the number of rods 30 is not limited to four. The rods 30 may be parallel to each other. The rods 30 may be separated from each other and arranged along edges of the top and bottom plates 10 and 20. The rods 30 arranged along the edges of the top and bottom plates 10 and 20 may be concentrated in a certain area. For example, the rods 30 may be concentrated on one side of the top and bottom plates 10 and 20. Because the rods 30 may be concentrated on one side, the semiconductor substrates 50 may be transferred through the other side on which the rods 30 are not arranged. For example, the semiconductor substrates 50 may be loaded into or removed from the boat 1 through the side on which the rods 30 are not arranged.

The rods 30 may be, but are not limited to, cylindrical. The rods 30 may contain at least one of quartz and SiC.

The buffer plates 40 may be n buffer plates 40 including first through nth buffer plates 40-1 through 40-n formed between the bottom plate 10 and the top plate 20, where n is a natural number equal to or greater than three. The buffer plates 40 may be arranged at intervals of a first distance dl between the bottom plate 10 and the top plate 20 along a lengthwise direction of the rods 30. For example, the buffer plates 40 may be arranged such that a distance between every two neighboring buffer plates 40 is the first distance d1.

Each of two neighboring buffer plates 40 may face each other. Therefore, the space between the bottom plate 10 and the top plate 20 may be divided into a plurality of compartments or subspaces that are equally spaced by the buffer plates 40. A subspace may be defined as a space between two neighboring buffer plates 40, into which a semiconductor substrate 50 can be loaded.

The buffer plates 40 may be, but are not limited to, circular plates. No apertures may be formed in the buffer plates 40. Therefore, after the boat 1 is loaded into the semiconductor device fabrication equipment 60 (see FIG. 5), a process performed on a semiconductor substrate 50 in a subspace may not be affected by the other subspaces because a processing gas cannot pass through the buffer plates 40. Thus, the independence of each subspace can be secured by the buffer plates 40.

The buffer plates 40 may be made of the same material as the rods 30. For example, the buffer plates 40 may contain at least one of, but are not limited to, quartz and SiC.

The buffer plates 40 may be connected to the rods 30 and thus attached in position. For example, side surfaces of the buffer plates 40 may contact each of the rods 30, and the side surface of one buffer plate 40 may be bonded to the rods 30. For example, the buffer plates 40 and the rods 30 may be formed as a single integral unit. However, the way that the buffer plates 40 and the rods 30 are connected is not limited to this method. Various methods attaching the buffer plates 40 within the boat 1 may be used.

The supports may support the semiconductor substrates 50 loaded in the boat 1. For example, a semiconductor substrate 50 loaded into a space between every two neighboring buffer plates 40 may be supported by a support.

One or more supports may be formed between every two neighboring buffer plates 40. Here, the same number of supports may be formed between every two neighboring buffer plates 40. For example, one support may be formed between every two neighboring buffer plates 40. However, example embodiments are not limited thereto. The same number of supports are formed between every two neighboring buffer plates 40 in order to load the same number of semiconductor substrates 50 into the space between every two neighboring buffer plates 40.

The size and shape of the supports are not limited as long as the supports can support the semiconductor substrates 50. In the boat 1 according to example embodiments, the supports may be slots 32 formed in the rods 30. For example, a plurality of slots 32 may be formed in each of the rods 30. The slots 32 may be arranged at regular intervals along the lengthwise direction of each rod 30. Specifically, one or more slots 32 may be formed in the space between every two neighboring buffer plates 40 along the lengthwise direction of each rod 30. For example, one slot 32 may be formed in each rod 30 in the space between every two neighboring buffer plates 40. However, example embodiments are not limited thereto.

The slots 32 may be arranged at regular intervals along the lengthwise direction of each rod 30, such that a distance d3 between an upper one of every two neighboring buffer plates 40 and a slot 32 is the same. Due to this arrangement of the slots 32, referring to FIG. 3, if a semiconductor substrate 50 is inserted into each of the slots 32, the distance between the semiconductor substrate 50 and the upper one of every two neighboring buffer plates 40 may be the same. Because the distance between the semiconductor substrate 50 and the upper one of every two neighboring buffer plates 40 is the same, each semiconductor substrate 50 can be processed to a uniform degree, regardless of a subspace of the boat 1 in which it is loaded.

The positions of the slots 32 will now be described in greater detail using two neighboring buffer plates 40. A distance d2 between a slot 32 and a lower one of two neighboring buffer plates 40 may be different from the distance d3 between the slot 32 and an upper one of the two neighboring buffer plates 40. For example, the distance d2 may be smaller than the distance d3 between.

A space between the lower one of the two neighboring buffer plates 40 and the slot 32 may be a space needed for a transfer robot to transfer a semiconductor substrate 50 into the boat 1. For example, the space between the lower one of the two neighboring buffer plates 40 and the slot 32 may not have a decisive effect on processing yield. Therefore, the distance d2 between the lower one of the two neighboring plates 40 and the slot 32 may be minimized to reduce the size of the boat 1.

The slots 32 may support the semiconductor substrates 50 loaded into the boat 1. Referring to FIGS. 3 and 4, side surfaces of the semiconductor substrates 50 may be inserted into the slots 32, respectively. Thus, the semiconductor substrates 50 may be supported by the slots 32. The semiconductor substrates 50 may be, but are not limited to, wafers.

The boat 1 according to example embodiments will now be described in more detail with reference to FIGS. 1 and 2 and using the first through third buffer plates 40-1 through 40-3.

The first through third buffer plates 40-1 through 40-3 may be arranged between the bottom plate 10 and the top plate 20 along the lengthwise direction of the rods 30 and may be separated from each other by the first distance dl. Specifically, the second buffer plate 40-2 may face the first buffer plate 40-1 and may be separated from the first buffer plate 40-1. In addition, the third buffer plate 40-3 may face the second buffer plate 40-2 and may be separated from the second buffer plate 40-2. A distance between the first buffer plate 40-1 and the second buffer plate 40-2 and a distance between the second buffer plate 40-2 and the third buffer plate 40-3 may all be equal to the first distance d1.

One or more slots 32 (i.e., supports) may be formed between the first buffer plate 40-1 and the second buffer plate 40-2 and between the second buffer plate 40-2 and the third buffer plate 40-3. The number of slots 32 formed between the first buffer plate 40-1 and the second buffer plate 40-2 may be equal to the number of slots 32 formed between the second buffer plate 40-2 and the third buffer plate 40-3.

The distance d2 between the first buffer plate 40-1 and a slot 32 may be different from the distance d3 between the second buffer plate 40-2 and the slot 32. For example, the distance d2 between the first buffer plate 40-1 and the slot 32 may be relatively smaller.

Referring to FIGS. 3 and 4, the semiconductor substrates 50 may be loaded into the boat 1 by inserting the semiconductor substrates 50 respectively into the slots 32 of the boat 1. As described above, the distance d3 between a semiconductor substrate 50 and the upper one of every two neighboring plates 40 may be the same.

The semiconductor substrates 50 may not be inserted into all of the slots 32. In other words, semiconductor substrates 50 may not be inserted into some of the slots 32. For example, the subspaces of the boat 1 according to example embodiments, into which the semiconductor substrates 50 can be loaded, are independent of each other due to the buffer plates 40. For example, the slots 32 may be formed such that one semiconductor substrate 50 can be inserted into each subspace of the boat 1. In addition, the distance d3 between the upper one of every two neighboring buffer plates 40 and a slot 32 is the same. Accordingly, the presence or absence of a semiconductor substrate 50 between the first and second buffer plates 40-1 and 40-2 does not affect a process performed on a semiconductor substrate 50 between the second and third buffer plates 40-2 and 40-3.

Accordingly, it may not be necessary to load a predetermined number of semiconductor substrates 50 into the boat 1. For example, even if an insufficient number of semiconductor substrates 50 are to be loaded, there is no need to use dummy wafers to meet a predetermined number of semiconductor substrates so as to increase processing yield. Furthermore, because the buffer plates 40 can be made of a material that has a minimum reaction with a processing gas, they can be used for a long time without replacement. Consequently, the boat 1 may reduce the processing cost and time and ensure uniform processing results.

The effects of the boat 1 will now be described with reference to FIG. 5. The boat 1 loaded with the semiconductor substrates 50 as shown in FIG. 3 may be loaded into a reaction chamber 70. Then, a gas supply device 80 may supply a processing gas into the reaction chamber 70. Accordingly, the semiconductor substrates 50 loaded in the boat 1 may be processed.

The degree to which a semiconductor substrate 50 is affected by the processing gas may be determined by, for example, a space between the semiconductor substrate 50 and another substrate disposed above (or adjacent to) the semiconductor substrate 50. In the boat 1, the slots 32 may be formed such that when a semiconductor substrate 50 is loaded into the space between every two neighboring buffer plates 40, the distance d3 between the semiconductor substrate 50 and each buffer plate 40 placed above the semiconductor substrate 50 is the same. Because the same distance d3 may be maintained between the semiconductor substrate 50 and each buffer plate 40 placed above the semiconductor substrate 50, all semiconductor substrates 50 loaded into the boat 1 may be affected to the same degree by the processing gas. This ensures uniform processing results, thus increasing processing yield.

Furthermore, each semiconductor substrate 50 loaded into the boat 1 may be positioned between two neighboring buffer plates 40. For example, the distance d3 between a semiconductor substrate 50 and a buffer plate 40 above the semiconductor substrate 50 may not be affected by a semiconductor substrate 50 loaded in another subspace. Because no semiconductor substrates 50 may be inserted into some of the slots 32 as described above, the number of semiconductor substrates 50 loaded into the boat 1 can be controlled and vary.

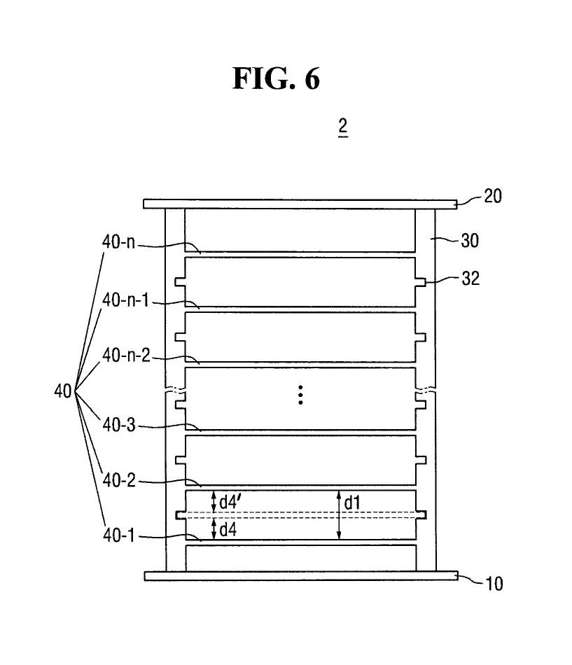

A boat according to another example embodiment will be described with reference to FIG. 6. For simplicity, the following description will focus on differences from the boat 1 according to the aforementioned example embodiment . FIG. 6 is a cross-sectional view of a boat 2 according to an example embodiment.

Referring to FIG. 6, in the boat 2 , a distance d4 between a lower one of every two neighboring buffer plates 40 and a slot 32 may be substantially equal to a distance d4′ between an upper one of the every two neighboring buffer plates 40 and the slot 32.

Specifically, a distance d4 between a first buffer plate 40-1 and a slot 32 may be substantially equal to a distance d4′ between a second buffer plate 40-2 and the slot 32. Accordingly, a distance d4 between the first buffer plate 40-1 and a semiconductor substrate 50 loaded into the boat 2 may be equal to a distance d4′ between the second buffer plate 40-2 and the semiconductor substrate 50.

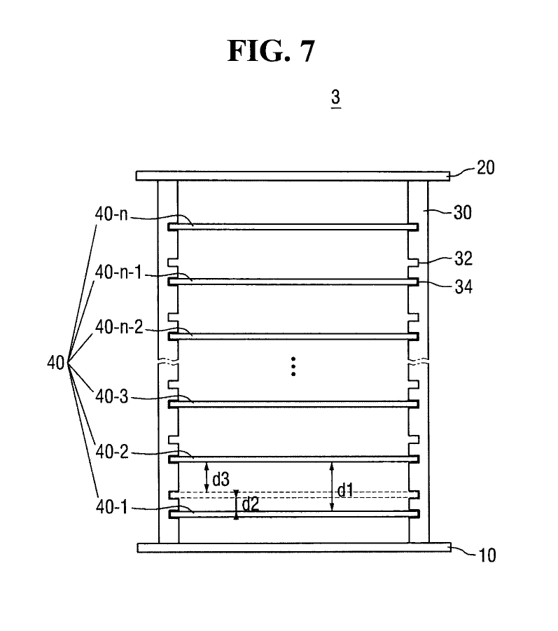

A boat according to a further example embodiment will be described with reference to FIG. 7. For simplicity, the following description will focus on differences from the boat 1 according to the aforementioned example embodiment. FIG. 7 is a cross-sectional view of a boat 3.

Referring to FIG. 7, each rod 30 may include buffer slots 34 which can support buffer plates 40, in addition to slots 32 which can support semiconductor substrates 50. For example, a buffer slot 34 may be formed between every two neighboring slots 32. The buffer plates 4 may be inserted into the buffer slots 34, respectively, and thus be attached to the boat 3.

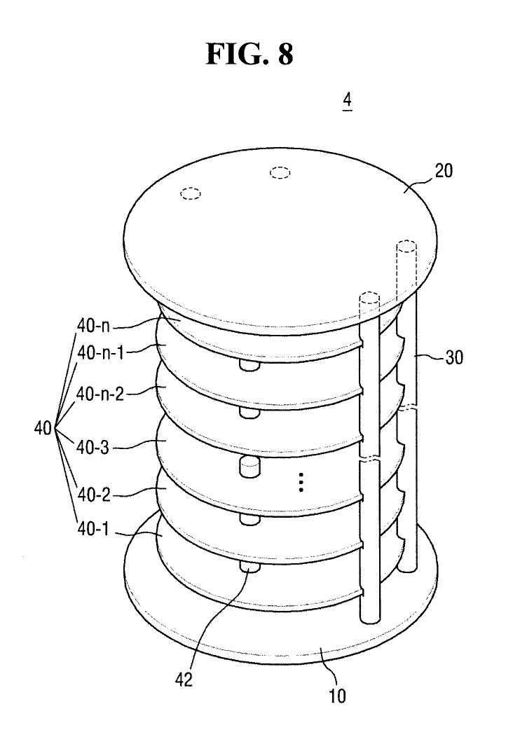

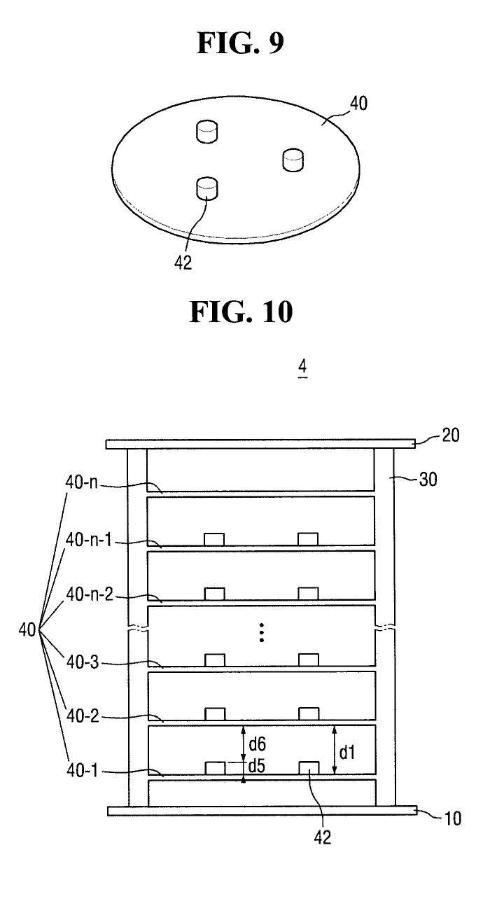

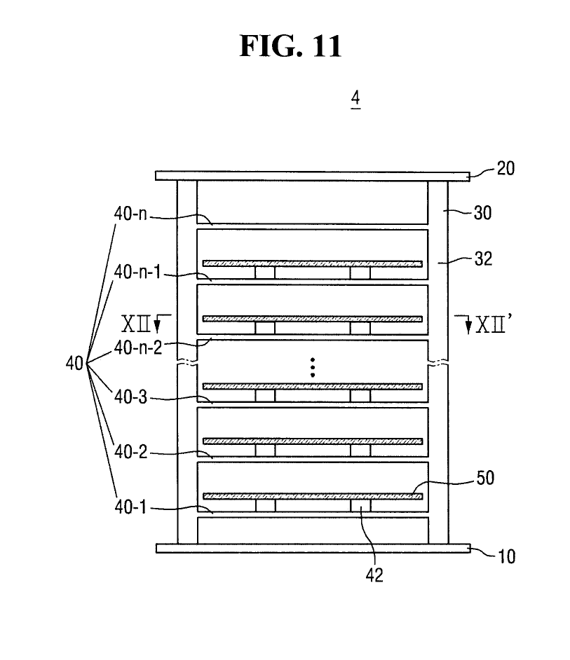

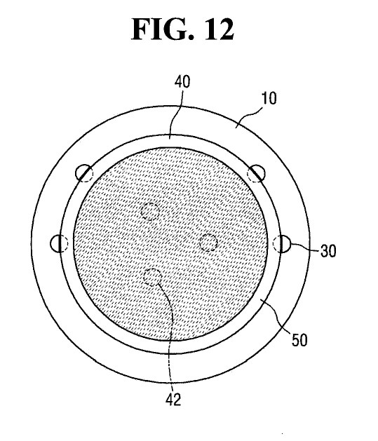

A boat according to some additional example embodiments will be described with reference to FIGS. 8 through 12. For simplicity, the following description will focus on differences from the boat 1 according to the aforementioned example embodiment. FIG. 8 is a perspective view of a boat 4. FIG. 9 is a perspective view of a buffer plate 40 included in the boat 4 of FIG. 8. FIG. 10 is a cross-sectional view of the boat 4 shown in FIG. 8. FIG. 11 is a cross-sectional view of the boat 4 of FIG. 8 loaded with semiconductor substrates 50. FIG. 12 is a plan view of a cross section of the boat 4, taken along the line XII-XII' of FIG. 11.

Referring to FIG. 8, each rod 30 may not include supports which can support the semiconductor substrates 50. Therefore, slots 32 may not be formed in each rod 30. Instead, each buffer plate 40 may include supports which can support a semiconductor substrate 50.

Specifically, referring to FIG. 9, supports which can support a semiconductor substrate 50 may be formed on a surface of each buffer plate 40. The supports may be, for example, first pins 42, which protrude from a surface of each buffer plate 40. In FIG. 9, three first pins 42 are arranged to form a triangle. However, the number of first pins 42 and a shape in which the first pins 42 are arranged is not limited to this example.

Referring to FIG. 10, the first pins 42 may have equal lengths. Therefore, a distance d6 between upper ends of the first pins 42, which are formed between every two neighboring buffer plates 40, and an upper one of the every two neighboring buffer plates 40 may be the same.

Specifically, a distance d5 between a first buffer plate 40-1 and respective upper ends of the first pins 42 may be different from a distance d6 between a second buffer plate 40-2 and the respective upper ends of the first pins 42. However, example embodiments are not limited thereto. The distance between the first buffer plate 40-1 and the respective upper ends of the first pins 42 may be equal to the distance between the second buffer plate 40-2 and the respective upper ends of the first pins 42.

Referring to FIG. 11, each semiconductor substrate 50 may be loaded on the first pins 42, and the first pins 42 may support the semiconductor substrate 50. Referring to FIG. 12, a side surface of each semiconductor substrate 50 may not contact the rods 30. For example, a diameter of each semiconductor substrate 50 may be smaller than that of each buffer plate 40.

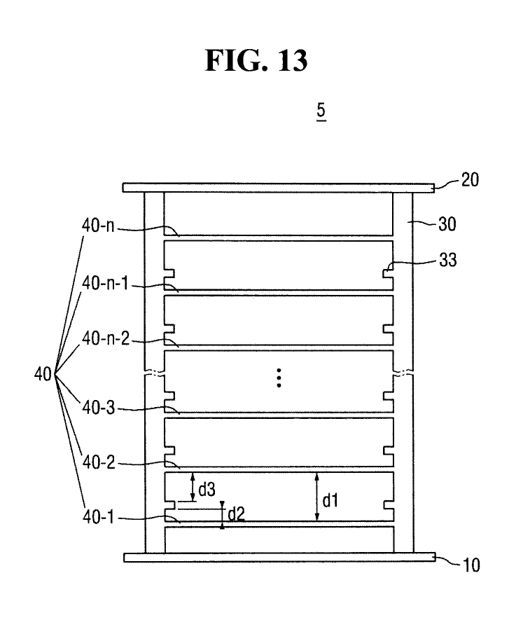

A boat according to some example embodiments will be described with reference to FIG. 13. For simplicity, the following description will focus on differences from the boat 1 according to the aforementioned example embodiment. FIG. 13 is a cross-sectional view of a boat 5.

Referring to FIG. 13, supports formed in the boat 5 may not be slots 32. The slots 32 may not be formed in each rod 30. Instead, a plurality of second pins 30 may protrude from each rod 30 in a direction perpendicular to a lengthwise direction of each rod 30. The second pins 30 may be arranged at regular intervals along the lengthwise direction of each rod 30. For example, a second pin 30 may be formed between every two neighboring buffer plates 40 along the lengthwise direction of each rod 30. Semiconductor substrates 50 may be loaded into the boat 5 such that edges thereof are placed on the second pins 33.

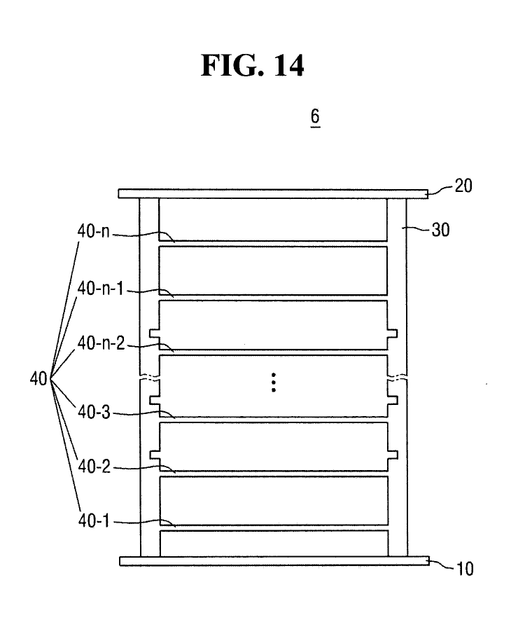

A boat according to some example embodiments will be described with reference to FIG. 14. For simplicity, the following description will focus on differences from the boat 1 according to the aforementioned example embodiment. FIG. 14 is a cross-sectional view of a boat 6.

Referring to FIG. 14, some subspace between two neighboring buffer plates 40 may not have a slot 32 which can support a semiconductor substrate 50. For example, the slot 32 may not be formed in a subspace adjacent to each of a top plate 20 and a bottom plate 10. In the boat 6 loaded into semiconductor device fabrication equipment 60, the flow of a processing gas may be unstable near the top plate 20 and the bottom plate 10. Therefore, processing results of semiconductor substrates 50 located near the top plate 20 and the bottom plate 10 may not be uniform. For this reason, the slot 32 may not be formed in a space between two buffer plates 40, which is adjacent to each of the top plate 20 and the bottom plate 10.

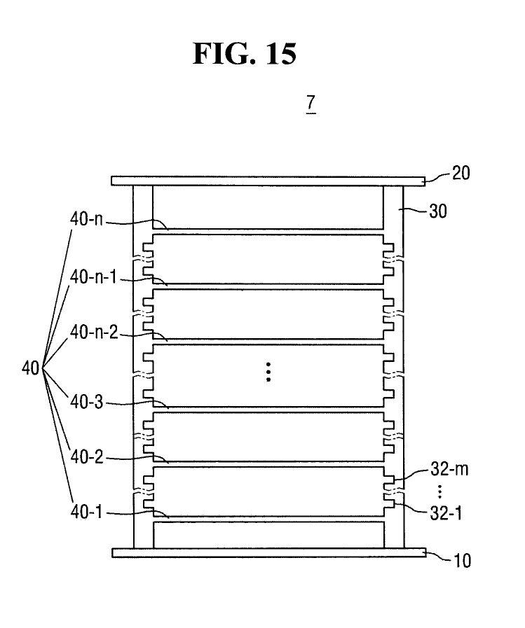

A boat according to some example embodiments will be described with reference to FIG. 15. For simplicity, the following description will focus on differences from the boat 1 according to the aforementioned example embodiment. FIG. 15 is a cross-sectional view of a boat 7.

Referring to FIG. 15, in the boat 7, m supports (m is a natural number equal to or greater than one) may be formed in a space between every two neighboring buffer plates 40. For example, a plurality of slots 32-1 through 32-m may be formed in the space between every two neighboring buffer plates 40.

While the present inventive concepts have been particularly shown and described with reference to example embodiments thereof, it will be understood by those of ordinary skill in the art that various changes in form and details may be made therein without departing from the spirit and scope of the present inventive concepts as defined by the following claims. It is therefore desired that the present example embodiments be considered in all respects as illustrative and not restrictive, reference being made to the appended claims rather than the foregoing description to indicate the scope of the inventive concepts.

What is claimed is:

1. A boat for loading substrates, the boat comprising:
a top plate and a bottom plate separated from each other;
a rod between the top plate and the bottom plate, the rod configured to extend from the bottom plate to the top plate;
a plurality of buffer plates between the top plate and the bottom plate, the plurality of buffer plates separated from each other by a first distance along a lengthwise direction of the rod; and
a support between a first buffer plate and a second buffer plate, the first buffer plate and the second buffer plate neighboring each other, the support configured to support a substrate.

2. The boat of claim 1, wherein a number of the buffer plates is equal to or greater than three.

3. The boat of claim 1, further comprising:
a plurality of supports, each of the plurality of supports disposed between a respective neighboring pair of the buffer plates.

4. The boat of claim 3, wherein a same number of the supports are disposed between each neighboring pair of the buffer plates.

5. The boat of claim 1, wherein a distance between the first buffer plate and the support is different from a distance between the second plate and the support.

6. The boat of claim 1, wherein side surfaces of the buffer plates are configured to contact the rod.

7. The boat of claim 1, wherein the rod is made of a same material as the buffer plates.

8. The boat of claim 1, wherein the buffer plates have no apertures.

9. The boat of claim 1, wherein the support is a slot in the rod.

10. The boat of claim 1, wherein the support is a pin, the pin protruding from a top surface of one of the first and second buffer plates.

11. The boat of claim 7, wherein the support is a pin protruding from the rod.

12. A boat for loading semiconductor substrates, the boat comprising:
a first buffer plate;
a second buffer plate facing the first buffer plate, the second buffer plate separated from the first buffer plate;
in first supports between the first buffer plate and the second buffer plate, the first supports configured to support substrates;
a third buffer plate facing the second buffer plate, the third buffer plate separated from the second buffer plate; and
m second supports between the second buffer plate and the third buffer plate, the second supports configured to support substrates, and
where m is a natural number equal to or greater than one.

13. The boat of claim 12, wherein a distance between the first buffer plate and the second buffer plate is equal to a distance between the second buffer plate and the third buffer plate.

14. The boat of claim 12, further comprising:
a rod extending from the first buffer plate to the third buffer plate, the rod configured to contact side surfaces of the first through third buffer plates.

15. The boat of claim 14, wherein the rod is made of a same material as the first through third buffer plates.

16. The boat of claim 14, wherein the first and second supports are slots in the rod.

17. A boat for loading substrates, the boat comprising:
a plurality of compartments; and
at least one support associated with each of the compartments, the at least one support configured to receive a substrate.

18. The boat of claim 17, wherein the compartments have a same size.

19. The boat of claim 17, wherein a position of the support for each of the compartments is the same.

20. The boat of claim 17, wherein the compartments are defined by spaced, parallel plates.
